(19) United States
(12) Patent Application Publication
(10) Pub. No.: US 2026/0245845 A1
(43) Pub. Date: Aug. 20, 2026

(54) METHODS AND SYSTEMS FOR ARC SUPPRESSION DURING SEMICONDUCTOR FABRICATION PROCESSES

(71) Applicant: Applied Materials, Inc., Santa Clara, CA (US)

(72) Inventors: Mingjie LI, Santa Clara, CA (US); Jeevan SHANBHAG, Dublin, CA (US); Tsutomu TANAKA, Santa Clara, CA (US); Bryan LIAO, Sunnyvale, CA (US); Allan HE, Beaverton, OR (US); Sarah Michelle BOBEK, Santa Clara, CA (US); Dan ZHU, Pleasanton, CA (US); Jun FENG, Santa Clara, CA (US); Dmitry A. DZILNO, Sunnyvale, CA (US); Weiyi LEE, Fremont, CA (US)

(73) Assignee: Applied Materials, Inc., Santa Clara, CA (US)

(21) Appl. No.: 19/054,640

(22) Filed: Feb. 14, 2025

(51) Int. Cl. H01J 37/32; H01L 21/02

(52) U.S. Cl. CPC H01J 37/32944; H01J 37/32146; H01J 2237/3321; H10P 14/6336

(57) ABSTRACT

The techniques described herein relate to suppression of arcs during plasma-based semiconductor processes. The techniques can include delivering radio-frequency (RF) power a plasma in a semiconductor processing chamber. The techniques can include detecting a first indication of a first arc event in the semiconductor processing chamber. In response to detecting the first indication of the first arc event, causing the RF power to the plasma to pulse. Causing the RF power to the plasma to pulse can include repeatedly causing the RF power to pulse on and off to suppress the first arc event.

### TECHNICAL FIELD

This disclosure generally describes methods and systems for managing the creation and power of arcs during plasma-based semiconductor fabrication processes. More specifically, this disclosure describes arc suppression techniques by manipulating the radio frequency power delivered to the plasma.

### BACKGROUND

In the field of semiconductor manufacturing, the application of plasma-enhanced processes and other plasma-based processes have emerged as critical techniques for improving the efficiency and quality of semiconductor fabrication processes. These processes leverage ionized gases to create highly reactive species that can facilitate the growth of thin films, etch substrates, and modify surface properties. When radio frequency power is delivered to the plasma, arcing can occur. Arcing is a sudden increase in current flow through the plasma. Some arcing can be minor while some arcing can be more severe. Severe arcing can cause damage to wafers during plasma-enhanced processes and other plasma-based processes. The damage from severe arcing can affect the yield of semiconductor devices from the wafer, or the wafer can be damaged sufficiently that it is not suitable for further semiconductor device fabrication. Severe arcing can also damage the chamber hardware. On the other hand, minor arcing is permissible because it may only cause minor damage and may negligibly affect yields.

Additionally, being able to characterize whether arcing is minor or severe can be used to efficiently manage radio frequency power delivered to plasma during plasma-enhanced and plasma-based processes. To address these issues, there is a need for innovative approaches that enhance both the balancing of high amounts of radio frequency power, reducing severe arcing, and characterizing different types of arcing.

### SUMMARY

In some embodiments, a method of suppressing arcing during processing of a semiconductor wafer by a plasma-based semiconductor fabrication process can include delivering radio-frequency power to a plasma in a semiconductor processing chamber, wherein the semiconductor processing chamber is configured to perform a plasma-based semiconductor process; detecting a first indication of a first arc event in the semiconductor processing chamber; and in response to detecting the first indication of the first arc event, pulsing the RF power to the plasma, wherein pulsing the RF power to the plasma comprises repeatedly pulsing the RF power on and off to suppress the first arc event.

In some embodiments, a system may include a memory configured to store computer-executable instructions; and one or more processors in communication with the memory and configured to access the memory and execute the computer-executable instructions to: deliver radio-frequency power to a plasma in a semiconductor processing chamber, wherein the semiconductor processing chamber is configured to perform a plasma-based semiconductor process; detect a first indication of a first arc event in the semiconductor processing chamber; and in response to detecting the first indication of the first arc event, pulse the RF power to the plasma, wherein pulsing the RF power to the plasma includes: repeatedly pulsing the RF power on and off to suppress the first arc event.

In some embodiments, one or more non-transitory computer-readable media comprising computer-executable instructions that, when executed by one or more processors of a computer system, cause the one or more processors to perform operations including: causing radio-frequency power to be delivered to a plasma in a semiconductor processing chamber, wherein the semiconductor processing chamber is configured to perform a plasma-based semiconductor process; detecting a first indication of a first arc event in the semiconductor processing chamber; and in response to detecting the first indication of the first arc event, causing the RF power to the plasma to pulse, wherein causing the RF power to the plasma to pulse includes: repeatedly causing the RF power to pulse on and off to suppress the first arc event.

In any embodiments, any and all of the following features may be implemented in any combination and without limitation. In some examples, the method can include in response to pulsing the RF power to the plasma, monitoring the semiconductor processing chamber to detect whether a second indication of a second arc event for a first duration occurs. In some examples, the method can include in response to detecting the second indication of the second arc event during the first duration, delivering one or more bursts of RF power to the plasma. In some examples, the method can include in response to not detecting the second indication of the second arc event during the first duration, delivering a third amount of RF power to the plasma. In some examples, the method can include delivering power to an electrostatic chuck of the semiconductor processing chamber; and in response to detecting the second indication of the second arc event during the first duration, refraining from delivering power to the electrostatic chuck. In some examples, the RF power can be high-frequency RF power, and wherein the method can include delivering low-frequency RF power to the plasma in the semiconductor processing chamber; and in response to detecting the second indication of the second arc event during the first duration, refraining from delivering low-frequency RF power to the plasma.

In some examples, the duration can be 1 millisecond. In some examples, the RF power can be 2000 watts. In some examples, pulsing the RF power to the plasma can have a 50% duty cycle. In some examples, the plasma-based semiconductor process is a plasma-enhanced chemical vapor deposition (PECVD) process. In some examples, detecting the first indication of the first arc event can include detecting a reflected power above a threshold at a generator of the RF power. In some examples, the threshold can be 100 watts. In some examples, the threshold can be half of the RF power delivered to the plasma. In some examples, the method can include in response to causing the RF power to the plasma to pulse, monitoring the semiconductor processing chamber to detect whether a second indication of a second arc event for a third duration occurs, wherein detecting the second indication of the second arc event includes detecting a reflected power above a second threshold at a generator of the RF power. In some examples, the one or more bursts of RF power to the plasma includes at least two bursts of RF power to the plasma. In some examples, the radio-frequency (RF) power to be delivered to a plasma in a semiconductor processing chamber can be a first amount of RF power, and wherein causing the RF power to the plasma to pulse can cause a second amount of RF power to pulse on and off, and wherein the first amount of RF power and the second amount of RF power can be different. The threshold can be a 50% increase above a steady state of RF power.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a schematic cross-sectional view of an exemplary processing chamber according to some embodiments of the present technology.

FIG. 2 illustrates diagrams of forward power and reflected power when using the techniques described herein, according to some embodiments.

FIG. 3 illustrates diagrams of forward power and reflected power when using the techniques described herein, according to some embodiments.

FIG. 4 illustrates a flowchart of a method of suppressing and/or managing arcs during semiconductor processes, according to some embodiments.

FIG. 5 illustrates an exemplary computer system, in which various embodiments may be implemented.

### DETAILED DESCRIPTION

Plasma-enhanced and plasma-based processes can be used to grow thin films, etch substrates, and modify surface properties. When radio frequency (RF) power is delivered to the plasma, arcing can occur. Arcing is a sudden increase in current flow through the plasma. Arcing can be minor or severe. Severe arcing can cause damage to semiconductor wafers thus lowering the yield of semiconductor devices on the wafer or make the wafer unsuitable for further semiconductor device fabrication. On the other hand, minor arcing may only cause minor damage and negligibly affect yields.

The techniques (for example, methods and systems) described herein can decrease severe arcing while enabling large amounts of RF power to be delivered to the plasma of plasma-enhanced and plasma-based processes. Arcing causes shorting through the plasma and thus creates a large impedance change. The large impedance change in the plasma causes RF power to be reflected back to the generator. In this way, arcing (or potential future arcing) can be detected when reflected RF power exceeds a threshold at the RF power generator. When reflected RF power exceeds the threshold, the generator can turn off the RF power being delivered to the plasma to extinguish arcing to minimize or prevent damage to the chamber hardware or the wafer. However, the break period for turning off the RF power can also affect the outcome of the plasma-enhanced or plasma-based process. As such, the break period can be minimized in order to minimize the effect on the outcome of the process.

In one example, the generator can break the RF power delivered to the plasma by turning the generator off and on a single time to create the break period. In some examples, the generator can repeatedly pulse the RF power delivered to the plasma by repeatedly turning the generator off and on to create multiple break periods. Pulsing or breaking the RF power delivered to the plasma can prevent further arcing or decrease the severity of the arcing. After pulsing or breaking the RF power, the RF power can be restored and delivered to the plasma. The reflected power detector can determine if reflected RF power still exceeds a threshold and pulse or break the RF power again if necessary. Each set of pulses or a single break of turning the generator off and on can be referred to as a burst. If a threshold number of attempts to stop arcing (for example, via breaks, pulses, or bursts) is reached, a computer system (also referred to as the system) can shut off the RF power generator. If the reflected power detector can determine that the reflected power does not exceed a threshold (for example, the reflected power is at or below a threshold), then the RF power can continue to be delivered to the plasma. Additionally, the system can determine that the arcing was severe and determine that the wafer is likely too damaged to provide sufficient yields.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

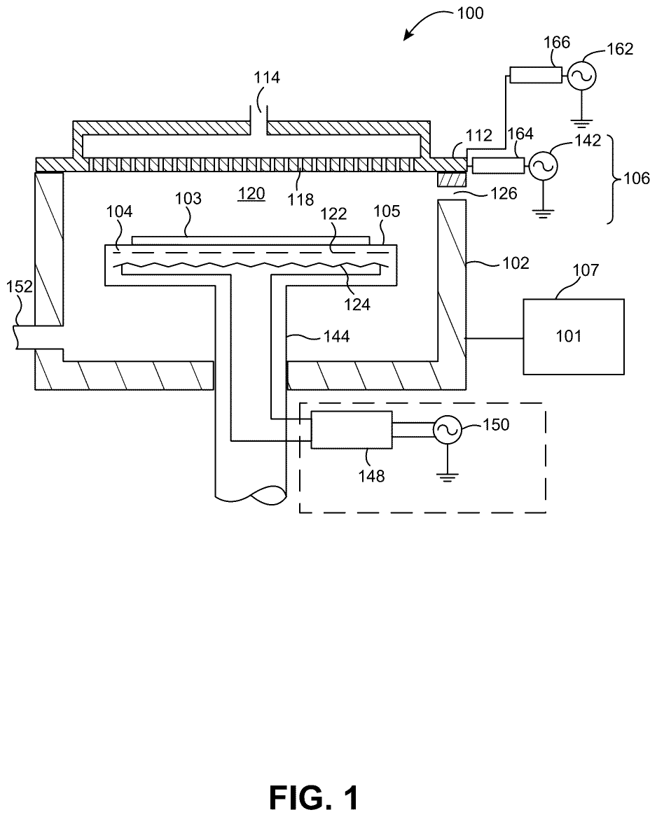

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source. The gas distributor 112 may be coupled with the first source of electric power 142 through a filter 164, which may be an impedance matching circuit. The gas distributor 112 may be coupled with a second source of electric power 162, such as an RF generator, RF power source, DC power source, pulsed DC power source, pulsed RF power source, or any other power source that may be coupled with the processing chamber. The gas distributor 112 may be coupled with the second source of electric power 162 through a filter 166, which may be an impedance matching circuit. In some examples, the first source of electric power 142 can be a high-frequency RF power generator. In some examples, the second source of electric power 162 can be a low-frequency RF power generator. For example, the first source of electrical energy 142 can be at 13.56 MHz and the second source of electric power 162 can be at 350 kHz.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements.

A second electrode 124, which may be a bias electrode and/or an electrostatic chucking electrode, may be coupled with the substrate support 104. The second electrode may be coupled with a third source of electric power 150 through a RF filter 148. The third source of electric power 150 may be DC power, pulsed DC power, RF bias power, a pulsed RF source or bias power, or a combination of these or other power sources. In some embodiments, the third source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

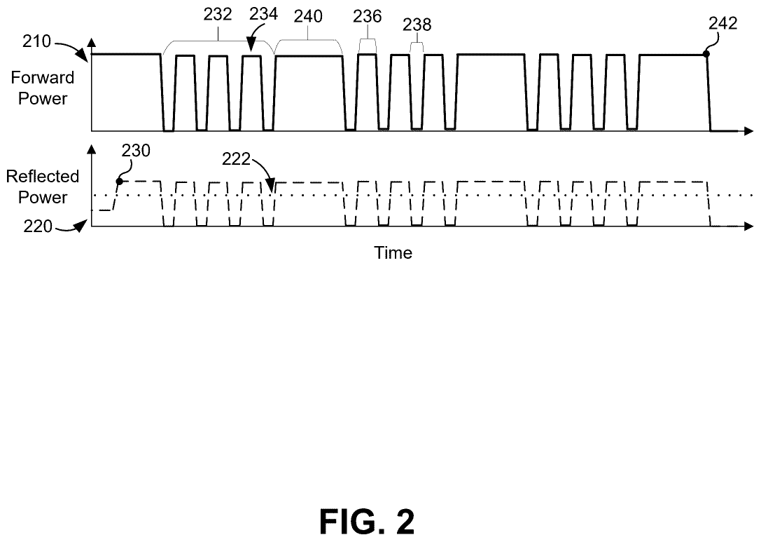

FIG. 2 illustrates both a forward power diagram 210 and a reflected power diagram 220 as detected at or near the RF generator (for example, the first source of electric power 142 of FIG. 1) in order to describe the techniques herein related to plasma-enhanced and plasma-based processes (for example, plasma-enhanced chemical vapor deposition). The forward power diagram 210 represents the RF power being delivered to the plasma. The reflected power diagram 220 represents the reflected power detected at or near the RF generator (which can also be referred to as the generator or the RF power generator herein). The forward power diagram 210 and the reflected power diagram 220 have power as the y-axis and time as the x-axis. For purposes of the diagrams, the forward power diagram 210 and the reflected power diagram 220 are meant to use the same power and time scale along their respective axes.

As seen in forward power diagram 210, RF power is delivered to the plasma in the semiconductor processing chamber. At approximately the time associated with the point 230, arcing occurs in the semiconductor processing chamber. The shorting caused by the arcing creates a large change in the impedance of a current path through the plasma. The large change in the impedance of the current path through the plasma is observed at the RF power generator. The large change in impedance at the RF power generator causes a shift in the reflected power detected at the RF power generator. When the reflected power exceeds the threshold 222, sufficient arcing has occurred or there is high potential for an arc to occur for the arc suppression techniques described herein to be utilized. In this way, the arc suppression techniques described herein can both prevent the occurrence of arcing as well as reduce arcing after arcing has occurred.

After arcing has been detected at point 230, the RF generator can apply a break in RF power by turning off the RF power delivered to the plasma for a period and then turning on the RF power delivered to the plasma. In some examples, the RF generator can apply one or more bursts of RF power by alternating between a power-on and a power-off state. As shown in the forward power diagram 210, a first burst 232 can include a break of turning off the RF power delivered to the plasma for a period and then turning on the RF power delivered to the plasma, or one or more pulses of RF power. In the example shown in FIG. 2, the first burst includes 3 pulses including a first pulse 234. Many parameters of a burst can be adjusted or controlled. Example parameters include the number of pulses, the pulse duration 236, and the off duration 238. The pulse duration 236 can be used to describe how long the intended forward power is delivered to the plasma. In some examples, the pulse duration can be used to describe the length of time between when power is delivered by the RF generator and when power is not delivered by the RF generator (for example, the RF generator refrains from delivering power to the plasma). The off duration 238 can be used to describe how long forward power is not delivered to the plasma. For example, the RF generator can refrain from delivering forward power to the plasma. In some examples, a duty cycle is used to define the pulse duration 236 and the off duration 238 in combination with a period duration. For example, a period duration can be the combination of the pulse duration 236 and the off duration 238. The duty cycle can represent the percentage of the period duration where the forward power is delivered by the RF generator to the plasma. For example, a 50% duty cycle can represent that the pulse duration 236 is approximately equal to the off duration 238 and half of the period duration.

The pulse duration 236 and the off duration 238 can be any range of time from 1 nanosecond to 10 seconds. For example, the pulse duration 236 and the off duration 238 can be about or less than 100 milliseconds, about or less than 10 milliseconds, about or less than 1 millisecond, about or less than 100 microseconds, about or less than 10 microseconds, about or less than 1 microseconds, about or less than 100 nanoseconds, about or less than 10 nanoseconds, or less.

Determining the pulse duration 236 and the off duration 238 can be based on a variety of factors including the composition of the plasma, the amount of power being supplied to the plasma, the composition of the wafer, the type of process, and the capabilities of the RF generator. In some examples, the pulse duration 236 and the off duration 238 are the same. In some examples, the pulse duration 236 and the off duration 238 are not the same. Pulse duration 236 and off duration 238 can affect the speed of completion or the completion rate of the plasma-based process. The pulse duration 236 and the off duration 238 can be determined based on the gas used, the pressure in the processing chamber, electrode spacing in the processing chamber, and the amount of power being delivered to the plasma.

The number of pulses in a burst can also be adjusted or controlled. In the forward power diagram 210 and the reflected power diagram 220, the number of pulses per burst is three. However, any suitable number of pulses can be used. For example, the number of pulses in a burst can be zero (also referred to as a break where the RF power is switched off once and switched back on) up to a million pulses. In some examples, more than a million pulses can be used in a single burst. In some examples, a burst can have 0 pulses (also referred to as a break), or 1, 2, 3, 4, 5, 10, 20, or 100 pulses. The number of pulses can be determined based on the gas used, the pressure in the processing chamber, electrode spacing in the processing chamber, and the amount of power being delivered to the plasma.

Any suitable amount of forward power can be used. In some examples, the forward power can be about or less than 5000 watts, about or less than 4500 watts, about or less than 4000 watts, about or less than 3500 watts, about or less than 3000 watts, about or less than 2500 watts, about or less than 2000 watts, about or less than 1500 watts, about or less than 1000 watts, or about or less than 500 watts, or less.

Any suitable threshold 222 for reflected power can be used for initiating bursts of RF power. In some examples, the threshold 222 can be about or less than 1000 watts, about or less than 900 watts, about or less than 800 watts, about or less than 700 watts, about or less than 600 watts, about or less than 500 watts, about or less than 400 watts, about or less than 300 watts, about or less than 200 watts, about or less than 100 watts, or less. In some examples, the threshold 222 can be a percentage in relation to the forward power delivered by the RF generator. In some examples, the threshold 222 can be about or less than 100% of the forward power, about or less than 95% of the forward power, about or less than 90% of the forward power, about or less than 85% of the forward power, about or less than 80% of the forward power, about or less than 75% of the forward power, about or less than 70% of the forward power, about or less than 65% of the forward power, about or less than 60% of the forward power, about or less than 55% of the forward power, about or less than 50% of the forward power, about or less than 45% of the forward power, about or less than 40% of the forward power, about or less than 35% of the forward power, about or less than 30% of the forward power, about or less than 25% of the forward power, about or less than 20% of the forward power, about or less than 15% of the forward power, about or less than 10% of the forward power, about or less than 5% of the forward power, or less. In some examples, the threshold 222 can be a percentage increase from a steady state of reflected power. For example, the steady state reflected power observed at the RF power generator can be 200 watts. The reflected power observed can be in a steady state if the reflected power stays approximately the same for a sufficient period of time. If the reflected power increases to 300 watts, this represents a 50% increase in reflected power. In some examples, the threshold 222 can be about or more than a 5% increase in reflected power, about or more than a 10% increase in reflected power, about or more than a 15% increase in reflected power, about or more than a 20% increase in reflected power, about or more than a 25% increase in reflected power, about or more than a 30% increase in reflected power, about or more than a 35% increase in reflected power, about or more than a 40% increase in reflected power, about or more than a 45% increase in reflected power, about or more than a 50% increase in reflected power, about or more than a 55% increase in reflected power, about or more than a 60% increase in reflected power, about or more than a 65% increase in reflected power, about or more than a 70% increase in reflected power, about or more than a 75% increase in reflected power, about or more than a 80% increase in reflected power, about or more than a 85% increase in reflected power, about or more than a 90% increase in reflected power, about or more than a 95% increase in reflected power, about or more than a 100% increase in reflected power, or more.

Once a burst (for example, a break in RF power or a set of pulses) is completed, the system can enter a detection period 240. The RF generator can apply a steady amount of forward power (for example, 100% of the original forward power prior to delivering bursts) for a detection period 240. The reflected power can be measured to see if the reflected power lowers below the threshold 222. The detection period 240 can be any suitable time period.

The detection period 240 can be any range of time from 1 nanosecond to 10 seconds. For example, the detection periods can be about or less than 100 milliseconds, about or less than 10 milliseconds, about or less than 1 millisecond, about or less than 100 microseconds, about or less than 10 microseconds, about or less than 1 microseconds, about or less than 100 nanoseconds, about or less than 10 nanoseconds, or less. In some examples, the detection period can be about or less than 50 microseconds.

If the reflected power is still above the threshold 222 after a burst, another burst (for example, a break in RF power or a set of pulses) can be initiated. For example, the forward power diagram 210 shows that three bursts were initiated prior to shutting down the RF generator at point 242. Any number of bursts can be used as a threshold number of bursts prior to shutting down the RF generator. After performing the threshold number of bursts and the reflected power is still above the threshold 222, the RF generator can be shut down. In some examples, the threshold number of bursts (for example, a break in RF power or a set of pulses) can be 1, 2, 3, 4, 5, 10, 20, or 100. In some examples, the RF generator can be a high frequency RF generator. If the threshold number of bursts is reached and the reflected power is still above the threshold 222, the high frequency RF generator can be shut down. Additionally, if the threshold number of bursts is reached and the reflected power is still above the threshold 222, all power sources associated with the processing chamber can be shut down. In some examples, if the threshold number of bursts is reached and the reflected power is still above the threshold 222, all power sources that influence power delivered to the plasma can be shut down. Additionally, if the threshold number of bursts is reached and the reflected power is still above the threshold 222, a low frequency RF generator associated with the semiconductor processing chamber can be shut down. Additionally, if the threshold number of bursts is reach and the reflected power is still above the threshold 222, the system can refrain from delivering power to an electrostatic chuck (for example, an electrostatic chucking electrode).

Arcs that are resolved prior to reaching the threshold number of bursts can be classified as micro-arcs. Arcs that are not resolved prior to reaching the threshold of bursts can be classified as severe arcs. A threshold number of micro-arcs can be used to determine whether a wafer is too damaged. If the wafer is subject to a threshold number of micro-arcs, the wafer can be removed and/or thrown away. In some examples, the threshold number of micro-arcs can be 1, 2, 3, 4, 5, 10, 20, or 100. A threshold number of severe arcs can be used to determine whether a wafer is too damaged. In some examples, the threshold number of severe arcs is one severe arc.

The number of bursts and other characteristics regarding bursts (for example, the number of pulses and the length of pulses) can be used to classify arcing events. Different arcing events may lead to different actions being performed on a wafer. For example, severe arcing (for example, the reflected power continues to exceed a threshold 222 during the pulsing of RF power) can lead to the immediate shutdown of processing in the processing chamber. IN some examples, the wafer can be stripped and cleaned in order to be processed via the plasma-based process again. In some examples, the wafer can be inspected for defects after severe arcing has occurred. In some examples, if the arcing is minor (for example, the reflected power falls to below a threshold 222 during the pulsing of RF power), the plasma-based process can continue and/or no action can be taken.

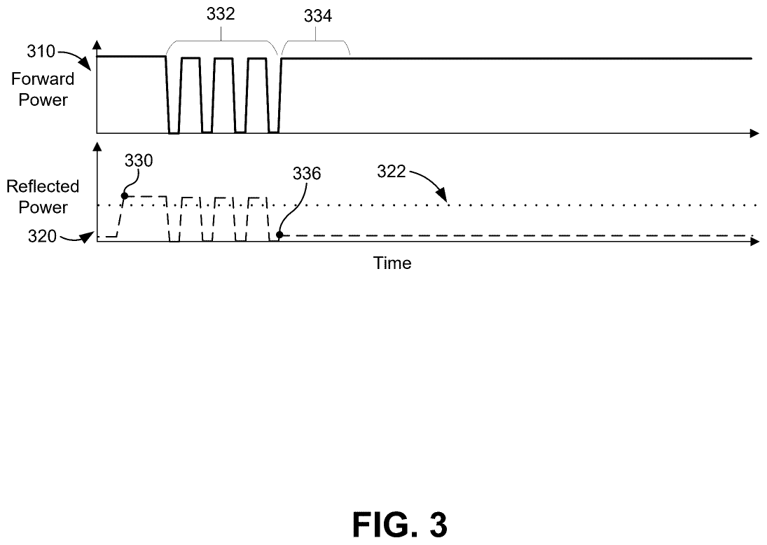

FIG. 3 illustrates both a forward power diagram 310 and a reflected power diagram 320 as detected at or near the RF generator (for example, the first source of electric power 142 of FIG. 1) in order to describe the techniques herein related to plasma-enhanced and plasma-based processes (for example, plasma-enhanced chemical vapor deposition). The forward power diagram 310 represents the RF power being delivered to the plasma. The reflected power diagram 320 represents the reflected power detected at or near the RF generator (which can also be referred to as the generator or the RF power generator herein). The forward power diagram 310 and the reflected power diagram 320 have power as the y-axis and time as the x-axis. For purposes of the diagrams, the forward power diagram 310 and the reflected power diagram 320 are meant to use the same power and time scale along their respective axes.

In the example of performing bursts as shown in FIG. 3, a single burst 332 is performed after arcing is detected at point 330. In this example, the single burst 332 included three pulses. After the burst 332 is completed, the reflected power is monitored while the forward power is delivered to the plasma. Here, at point 336 the reflected power does not return to a level above the threshold 322. In this example, the RF generator can refrain from performing another burst because the reflected power has lowered below the threshold 322 indicating that arcing is not occurring.

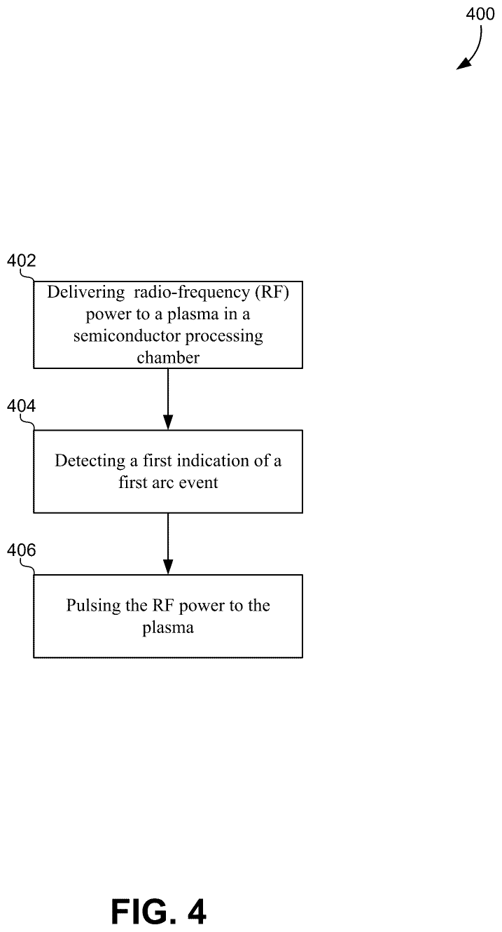

FIG. 4 illustrates a flowchart of a process 400 of suppressing arcing during processing of a semiconductor wafer by a plasma-based semiconductor fabrication process, according to some embodiments. This method may be performed by any of the semiconductor processing chambers described above in FIGS. 1-6. Additionally, some of the operations in this method may be executed by the controller of the chamber or another computer system. These processor operations may be embodied and stored instructions that are executed by the processor to cause the specified conditions to occur in the processing region.

It should be appreciated that the specific steps illustrated in FIG. 4 provide particular methods of forming films on substrates according to various embodiments. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods and processes described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

At operation 402, the process 400 can include delivering radio-frequency power to a plasma in a semiconductor processing chamber. The semiconductor processing chamber can be configured to perform a plasma-based semiconductor process. In some examples, one or more non-transitory computer-readable media comprising computer-executable instructions that, when executed by one or more processors of a computer system, cause the one or more processors to perform operations including causing radio-frequency power to be delivered to a plasma in a semiconductor processing chamber. In some examples, the RF power can be 2000 watts. In some examples, the plasma-based semiconductor process is a plasma-enhanced chemical vapor deposition process.

At operation 404, the process 400 can include detecting a first indication of a first arc event in the semiconductor processing chamber. Detecting the first indication of the first arc event can include detecting a reflected power above a threshold at a generator of the RF power. In some examples, the threshold can be 100 watts. In some examples, the threshold is reflected power that is half of the RF power delivered to the plasma. In some examples, the threshold is a 50% increase above a steady state of reflected RF power. The steady state of reflected RF power can be a range of reflected RF powers after the fabrication process has reached steady state.

At operation 406, the process 400 can include pulsing the RF power to the plasma. Pulsing the RF power to the plasma can be in response to detecting the first indication of the first arc event. Pulsing the RF power to the plasma can include repeatedly pulsing the RF power on and off to suppress the first arc event. In some examples, one or more non-transitory computer-readable media comprising computer-executable instructions that, when executed by one or more processors of a computer system, cause the one or more processors to perform operations including causing the RF power to the plasma to pulse. In some examples, pulsing the RF power to the plasma can have a 50% duty cycle.

The process 400 can further include in response to pulsing the RF power to the plasma, monitoring the semiconductor processing chamber to detect whether a second indication of a second arc event for a first duration occurs. The process 400 can further include in response to detecting the second indication of the second arc event during the first duration, delivering one or more bursts of RF power to the plasma. The process 400 can further include in response to not detecting the second indication of the second arc event during the first duration, delivering a third amount of RF power to the plasma. The process 400 can further include in response to detecting the second indication of the second arc event during the first duration, refraining from delivering RF power to the plasma. The process 400 can further include delivering power to an electrostatic chuck of the semiconductor processing chamber. The process 400 can further include in response to detecting the second indication of the second arc event during the first duration, refraining from delivering power to the electrostatic chuck. The process 400 can further include delivering low-frequency RF power to the plasma in the semiconductor processing chamber. The process 400 can further include in response to detecting the second indication of the second arc event during the first duration, refraining from delivering low-frequency RF power to the plasma.

The process 400 can further include in response to causing the RF power to the plasma to pulse, monitoring the semiconductor processing chamber to detect whether a second indication of a second arc event for a third duration occurs, wherein detecting the second indication of the second arc event includes detecting a reflected power above a second threshold at a generator of the RF power. The radio-frequency (RF) power to be delivered to a plasma in a semiconductor processing chamber can be a first amount of RF power, and wherein causing the RF power to the plasma to pulse can cause a second amount of RF power to pulse on and off, and wherein the first amount of RF power and the second amount of RF power can be different.

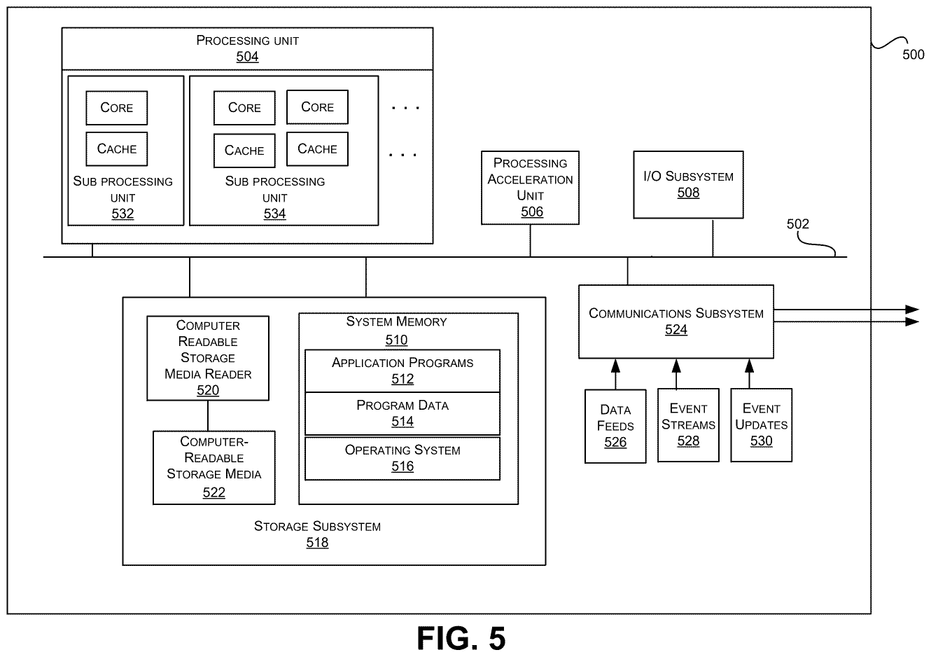

FIG. 5 illustrates an exemplary computer system 500, in which various embodiments may be implemented. The system 500 may be used to implement any of the computer systems described above. As shown in the figure, computer system 500 includes a processing unit 504 that communicates with a number of peripheral subsystems via a bus subsystem 502. These peripheral subsystems may include a processing acceleration unit 506, an I/O subsystem 508, a storage subsystem 518 and a communications subsystem 524. Storage subsystem 518 includes tangible computer-readable storage media 522 and a system memory 510.

Bus subsystem 502 provides a mechanism for letting the various components and subsystems of computer system 500 communicate with each other as intended. Although bus subsystem 502 is shown schematically as a single bus, alternative embodiments of the bus subsystem may utilize multiple buses. Bus subsystem 502 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, EtherCAT, and Peripheral Component Interconnect (PCI) bus, which can be implemented as a Mezzanine bus manufactured to the IEEE P1386.1 standard.

Processing unit 504, which can be implemented as one or more integrated circuits (e.g., a conventional microprocessor or microcontroller), controls the operation of computer system 500. One or more processors may be included in processing unit 504. These processors may include single core or multicore processors. In certain embodiments, processing unit 504 may be implemented as one or more independent processing units 532 and/or 534 with single or multicore processors included in each processing unit. In other embodiments, processing unit 504 may also be implemented as a quad-core processing unit formed by integrating two dual-core processors into a single chip.

In various embodiments, processing unit 504 can execute a variety of programs in response to program code and can maintain multiple concurrently executing programs or processes. At any given time, some or all of the program code to be executed can be resident in processor(s) 504 and/or in storage subsystem 518. Through suitable programming, processor(s) 504 can provide various functionalities described above. Computer system 500 may additionally include a processing acceleration unit 506, which can include a digital signal processor (DSP), a special-purpose processor, and/or the like.

I/O subsystem 508 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 500 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 500 may comprise a storage subsystem 518 that comprises software elements, shown as being currently located within a system memory 510. System memory 510 may store program instructions that are loadable and executable on processing unit 504, as well as data generated during the execution of these programs.

Depending on the configuration and type of computer system 500, system memory 510 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 504. In some implementations, system memory 510 may include multiple different types of memory, such as static random access memory (SRAM) or dynamic random access memory (DRAM). In some implementations, a basic input/output system (BIOS), containing the basic routines that help to transfer information between elements within computer system 500, such as during start-up, may typically be stored in the ROM. By way of example, and not limitation, system memory 510 also illustrates application programs 512, which may include client applications, Web browsers, mid-tier applications, relational database management systems (RDBMS), etc., program data 514, and an operating system 516.

Storage subsystem 518 may also provide a tangible computer-readable storage medium for storing the basic programming and data constructs that provide the functionality of some embodiments. Software (programs, code modules, instructions) that when executed by a processor provide the functionality described above may be stored in storage subsystem 518. These software modules or instructions may be executed by processing unit 504. Storage subsystem 518 may also provide a repository for storing data used in accordance with some embodiments.

Storage subsystem 500 may also include a computer-readable storage media reader 520 that can further be connected to computer-readable storage media 522. Together and, optionally, in combination with system memory 510, computer-readable storage media 522 may comprehensively represent remote, local, fixed, and/or removable storage devices plus storage media for temporarily and/or more permanently containing, storing, transmitting, and retrieving computer-readable information.

Computer-readable storage media 522 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information, and which can be accessed by computing system 500.

By way of example, computer-readable storage media 522 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 522 may include, but is not limited to, Zip® drives, flash memory cards, universal serial bus (USB) flash drives, secure digital (SD) cards, DVD disks, digital video tape, and the like. Computer-readable storage media 522 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 500.

Communications subsystem 524 provides an interface to other computer systems and networks. Communications subsystem 524 serves as an interface for receiving data from and transmitting data to other systems from computer system 500. For example, communications subsystem 524 may enable computer system 500 to connect to one or more devices via the Internet. In some embodiments communications subsystem 524 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 524 can provide wired network connectivity (e.g., Ethernet) in addition to or instead of a wireless interface.

In some embodiments, communications subsystem 524 may also receive input communication in the form of structured and/or unstructured data feeds 526, event streams 528, event updates 530, and the like on behalf of one or more users who may use computer system 500.

Additionally, communications subsystem 524 may also be configured to receive data in the form of continuous data streams, which may include event streams 528 of real-time events and/or event updates 530, that may be continuous or unbounded in nature with no explicit end. Examples of applications that generate continuous data may include, for example, sensor data applications, network performance measuring tools (e.g. network monitoring and traffic management applications), clickstream analysis tools, automobile traffic monitoring, and the like.

Communications subsystem 524 may also be configured to output the structured and/or unstructured data feeds 526, event streams 528, event updates 530, and the like to one or more databases that may be in communication with one or more streaming data source computers coupled to computer system 500.

Due to the ever-changing nature of computers and networks, the description of computer system 500 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of suppressing arcing during processing of a semiconductor wafer by a plasma-based semiconductor fabrication process, the method comprising:
delivering radio-frequency (RF) power to a plasma in a semiconductor processing chamber, wherein the semiconductor processing chamber is configured to perform a plasma-based semiconductor process;
detecting a first indication of a first arc event in the semiconductor processing chamber; and
in response to detecting the first indication of the first arc event, pulsing the RF power to the plasma, wherein pulsing the RF power to the plasma comprises repeatedly pulsing the RF power on and off to suppress the first arc event.

2. The method of claim 1, further comprising:
in response to pulsing the RF power to the plasma, monitoring the semiconductor processing chamber to detect whether a second indication of a second arc event for a first duration occurs.

3. The method of claim 2, further comprising:
in response to detecting the second indication of the second arc event during the first duration, delivering one or more bursts of RF power to the plasma.

4. The method of claim 2, further comprising:
in response to not detecting the second indication of the second arc event during the first duration, delivering a third amount of RF power to the plasma.

5. The method of claim 2, further comprising:
in response to detecting the second indication of the second arc event during the first duration, refraining from delivering RF power to the plasma.

6. The method of claim 2, further comprising:
delivering power to an electrostatic chuck of the semiconductor processing chamber; and
in response to detecting the second indication of the second arc event during the first duration, refraining from delivering power to the electrostatic chuck.

7. The method of claim 2, wherein the RF power is high-frequency RF power, and wherein the method further comprises:
delivering low-frequency RF power to the plasma in the semiconductor processing chamber; and
in response to detecting the second indication of the second arc event during the first duration, refraining from delivering low-frequency RF power to the plasma.

8. The method of claim 2, wherein the first duration is 1 millisecond.

9. A system, comprising:
a memory configured to store computer-executable instructions; and
one or more processors in communication with the memory and configured to access the memory and execute the computer-executable instructions to:
deliver radio-frequency (RF) power to a plasma in a semiconductor processing chamber, wherein the semiconductor processing chamber is configured to perform a plasma-based semiconductor process;
detect a first indication of a first arc event in the semiconductor processing chamber; and
in response to detecting the first indication of the first arc event, pulse the RF power to the plasma, wherein pulsing the RF power to the plasma comprises:
repeatedly pulsing the RF power on and off to suppress the first arc event.

10. The system of claim 9, wherein the RF power is 2000 watts.

11. The system of claim 9, wherein pulsing the RF power to the plasma has a 50% duty cycle.

12. The system of claim 9, wherein the plasma-based semiconductor process is a plasma-enhanced chemical vapor deposition (PECVD) process.

13. One or more non-transitory computer-readable media comprising computer-executable instructions that, when executed by one or more processors of a computer system, cause the one or more processors to perform operations comprising:
causing radio-frequency (RF) power to be delivered to a plasma in a semiconductor processing chamber, wherein the semiconductor processing chamber is configured to perform a plasma-based semiconductor process;
detecting a first indication of a first arc event in the semiconductor processing chamber; and
in response to detecting the first indication of the first arc event, causing the RF power to the plasma to pulse, wherein causing the RF power to the plasma to pulse comprises:
repeatedly causing the RF power to pulse on and off to suppress the first arc event.

14. The one or more non-transitory computer-readable media of claim 13, wherein detecting the first indication of the first arc event includes detecting a reflected power above a threshold at a generator of the RF power.

15. The one or more non-transitory computer-readable media of claim 14, wherein the threshold is 100 watts.

16. The one or more non-transitory computer-readable media of claim 14, wherein the threshold is half of the RF power delivered to the plasma.

17. The one or more non-transitory computer-readable media of claim 13, wherein the computer-executable instructions cause the one or more processors to perform further operations comprising:
in response to causing the RF power to the plasma to pulse, monitoring the semiconductor processing chamber to detect whether a second indication of a second arc event for a third duration occurs, wherein detecting the second indication of the second arc event includes detecting a reflected power above a second threshold at a generator of the RF power.

18. The one or more non-transitory computer-readable media of claim 13, wherein causing the RF power to the plasma to pulse includes at least two bursts of RF power to the plasma.

19. The one or more non-transitory computer-readable media of claim 13, wherein the radio-frequency (RF) power to be delivered to a plasma in a semiconductor processing chamber is a first amount of RF power, and wherein causing the RF power to the plasma to pulse causes a second amount of RF power to pulse on and off, and wherein the first amount of RF power and the second amount of RF power are different.

20. The one or more non-transitory computer-readable media of claim 14, wherein the threshold is a 50% increase above a steady state of RF power.
